(19) United States
(12) Patent Application Publication
(10) Pub. No.: US 2024/0120305 A1
(43) Pub. Date: Apr. 11, 2024

(54) PACKAGE ARCHITECTURE WITH INTERCONNECT MIGRATION BARRIERS

(71) Applicant: Intel Corporation, Santa Clara, CA (US)

(72) Inventors: Jeremy Ecton, Gilbert, AZ (US); Brandon C. Marin, Gilbert, AZ (US); Suddhasattwa Nad, Chandler, AZ (US); Srinivas V. Pietambaram, Chandler, AZ (US); Mohammad Mamunur Rahman, Gilbert, AZ (US)

(73) Assignee: Intel Corporation, Santa Clara, CA (US)

(21) Appl. No.: 17/938,784

(22) Filed: Oct. 7, 2022

(51) Int. Cl. H01L 23/00; H01L 23/538

(52) U.S. Cl. CPC H01L 24/16; H01L 23/5381; H01L 23/5383; H01L 23/5384; H01L 24/14; H01L 24/32; H01L 24/73; H01L 24/13; H01L 2224/13109; H01L 2224/13111; H01L 2224/13113; H01L 2224/13116; H01L 2224/13118; H01L 2224/13139; H01L 2224/13147; H01L 2224/13155; H01L 2224/1357; H01L 2224/13686; H01L 2224/1403; H01L 2224/16227; H01L 2224/32225; H01L 2224/73204

(57) ABSTRACT

Embodiments of a microelectronic assembly includes: a package substrate and an integrated circuit (IC) die coupled to a surface of the package substrate by first interconnects and second interconnects, the first interconnects and the second interconnects comprising solder. The first interconnects are larger than the second interconnects, the first interconnects and the second interconnects further comprise bumps on the IC die and bond-pads on the surface of the package substrate, with the solder coupled to the bumps and the bond-pads, lateral sides of the bumps have a coating of a material that prevents solder wicking, and the surface of the package substrate includes insulative baffles between the bond-pads.

### TECHNICAL FIELD

The present disclosure relates to techniques, methods, and apparatus directed to a package architecture with interconnect migration barriers.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly according to some embodiments of the present disclosure.

FIG. 1B is a schematic cross-sectional view of a portion of the microelectronic assembly of FIG. 1A according to some embodiments of the present disclosure.

FIG. 1C is a schematic perspective view of the portion of the microelectronic assembly of FIG. 1B.

FIG. 1D is a schematic cross-sectional view of a portion of the microelectronic assembly of FIG. 1A according to some embodiments of the present disclosure.

FIGS. 2A-2C are schematic cross-sectional views of a portion of an example microelectronic assembly during various stages of manufacture according to some embodiments of the present disclosure.

FIGS. 3A-3G are schematic cross-sectional views of a portion of an example microelectronic assembly during various stages of manufacture according to some embodiments of the present disclosure.

FIGS. 4A-4G are schematic cross-sectional views of a portion of an example microelectronic assembly during various stages of manufacture according to some embodiments of the present disclosure.

FIG. 5 is a cross-sectional view of a device package that includes one or more microelectronic assemblies in accordance with any of the embodiments disclosed herein.

FIG. 6 is a cross-sectional side view of a device assembly that includes one or more microelectronic assemblies in accordance with any of the embodiments disclosed herein.

FIG. 7 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller IC dies (e.g., chiplets, tiles) electrically coupled by bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected to create the functionalities of a monolithic IC. By using separate dies, each individual die can be designed and manufactured optimally for a particular functionality. Thus, by having different parts of the overall design separated into different dies, each one optimized in terms of design and manufacturing, the overall yield and cost of the combined die solution may be improved.

The connectivity between these dies is achievable by many different ways. For example, in 2.5D packaging solutions, a silicon interposer and through-substrate vias (TSVs), also called through-silicon vias where the substrate is silicon, connect dies at silicon-interconnect speed in a minimal footprint. In another example, called Embedded Multi-Die Interconnect Bridge (EMIB), a bridge die embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The 2.5D architecture with bridge dies and the 3D stacked architecture may also be combined using an omni-directional interconnect (ODI), in which EMIB chips are embedded in an organic mold compound, which allows for top-packaged chips to communicate with other chips horizontally using EMIB and vertically, using through-mold vias (TMVs) which are typically larger than TSVs.

In such emerging package architectures, pitches of interconnects in IC dies may be decreased from 55 micrometers to 45 micrometers and further to less than 30 micrometers, for example, to increase communication bandwidth and reduce silicon area commensurate with advances in semiconductor process technologies. In addition, it may be advantageous to maintain bump thickness variation (BTV) below 10 micrometers ease of assembly and yield enhancement, particularly for future generations of 2.5D or 3D package architecture. Such small BTV is challenging particularly for organic substrates that can have surface total thickness variations (TTV) of 40 micrometers or larger. Even on inorganic substrates such as glass with highly polished, flat surfaces, the presence of vias and regions of different metal densities can cause high TTVs. Yet, small TTVs can support correspondingly small BTVs, which in turn can enable thermo-compression bonding and similar advanced processes for die attach. Indeed, in 2.5D package architectures with a large number of bridge dies embedded in package substrates, low TTV is particularly important.

Processes such as buildup layer planarization using chemical mechanical polishing (CMP), and advanced lamination techniques for plating uniformity improvement and low TTVs are costly and expected to negatively impact factory capacity or output significantly without additional efforts or capital investment. In addition, while CMP planarization is applicable for plated copper bumps, it is not suited for plated solder bumps, as no existing planarization slurries are currently available on the market. Besides, plating uniformity improvement is limited by large panel sizes and form factors as well as variation in pad sizes on the same IC die.

Accordingly, embodiments described herein enable a microelectronic assembly that includes: a package substrate and an IC die coupled to a surface of the package substrate by first interconnects and second interconnects, the first interconnects and the second interconnects comprising solder. The first interconnects are larger than the second interconnects, the first interconnects and the second interconnects further comprise bumps on the IC die and bond-pads on the surface of the package substrate, with the solder coupled to the bumps and the bond-pads, lateral sides of the bumps have a coating of a material that prevents solder wicking, and the surface of the package substrate includes insulative baffles between the bond-pads.

Some embodiments of a package substrate as disclosed herein comprises: a core having a first organic dielectric material and through-dielectric vias (TDVs) in the first organic dielectric material; a redistribution layer comprising a second organic dielectric material and a conductive bond-pad of a first diameter; and a baffle layer on a surface of the package substrate, the baffle layer comprising an opening of a second diameter. The term “baffle layer” as used herein refers to a layer of material functioning at least as a baffle (e.g., structure that prevents, restrains, or regulates flow of a fluid, such as melted solder). The redistribution layer is between the core and the baffle layer, the bond-pad is at an interface between the redistribution layer and the baffle layer, the bond-pad is in the opening in the baffle layer, and the first diameter of the bond-pad is smaller than the second diameter of the opening.

In some other embodiments disclosed herein, the package substrate comprises a core comprising a first organic dielectric material and TDVs in the first organic dielectric material; a first layer comprising a second organic dielectric material and a conductive bond-pad of a first diameter; and a second layer on a surface of the package substrate, the second layer comprising an opening of a second diameter. The first layer is between the core and the second layer, the bond-pad is at an interface between the first layer and the second layer, the bond-pad is in the opening in the second layer, and the first diameter of the bond-pad is larger than the second diameter of the opening.

Embodiments as described herein can lessen the impact of BTV on thermal compression bonding (TCB) assembly yield and reduce likelihood of solder bridging or solder migration by incorporating solder baffles between the bond-pads on the package substrate. Furthermore, the bumps on the IC die would be protruded with a coating that inhibits solder wicking. Such an approach would widen the TCB process window and enable greater force to be applied to compensate for BTV with lower risk of solder bridging on account of protective baffles to prevent solder migration to neighboring interconnects. Thus, such techniques as described herein can enable higher yield for example, by reducing risk of solder bridging, accommodate a wider TCB window, for example, by permitting larger BTVs, and potentially enable tighter bump pitch with solder interconnects.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In SOI, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

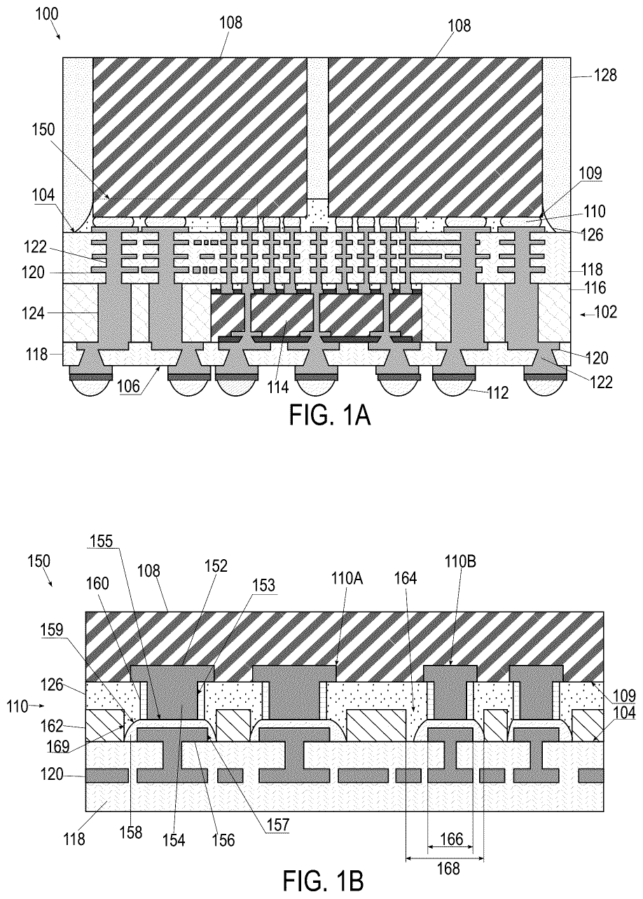

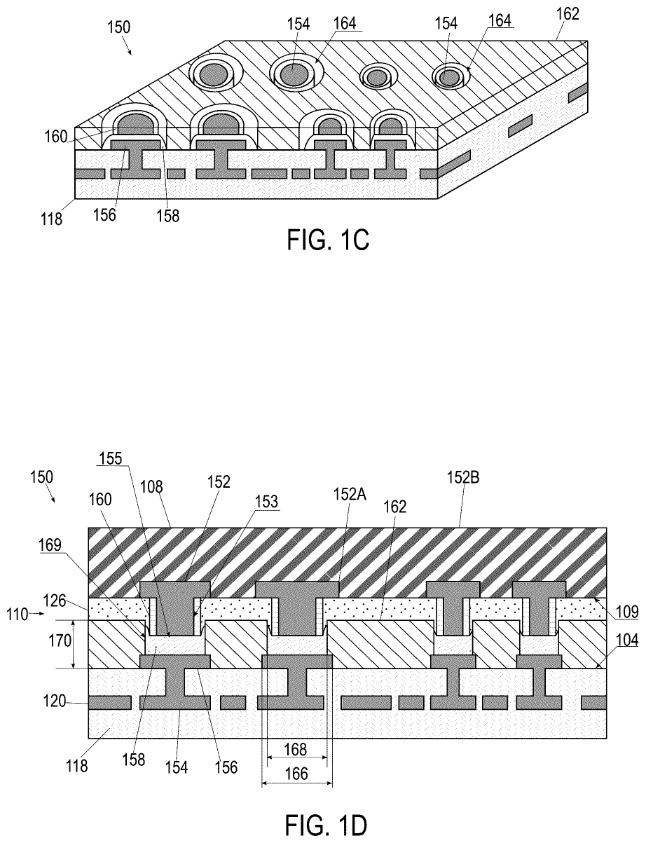

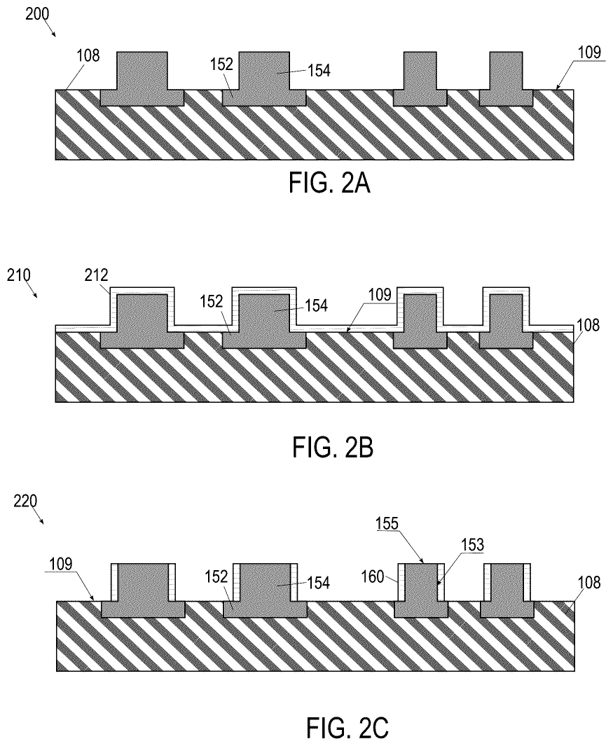

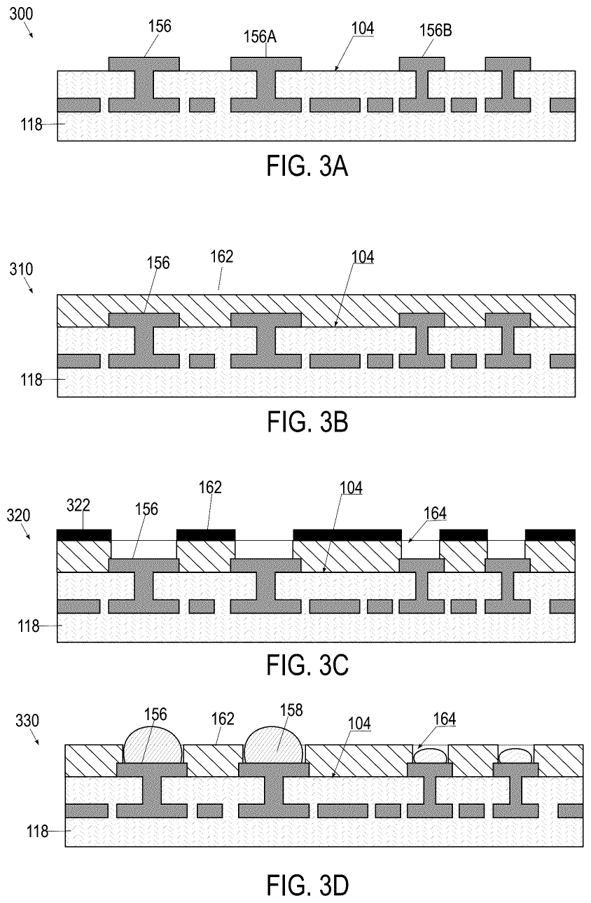

FIG. 1A is a schematic cross-sectional view of an example microelectronic assembly 100 according to some embodiments of the present disclosure. Microelectronic assembly 100 comprises a package substrate 102 having a surface 104 and an opposing surface 106. One or more IC dies 108 may be coupled on respective surfaces 109 to surface 104 of package substrate 102 by interconnects 110. Note that in some embodiments, the components labeled as 108 may correspond to an interposer structure, with IC dies coupled on top of the interposer structure so that the interposer structure is between the IC dies and package substrate 102. In such embodiments, interconnects 110 may be mid-level interconnects (MLI) and the structures described herein as being part of interconnects 110 apply to such MLIs without departing from the scope of the embodiments herein.

Interconnects 112 may be provisioned on surface 106, for example, to couple to a motherboard or other component. A bridge die 114 may be embedded in an organic dielectric material 116 in package substrate 102. Organic dielectric material 116 may comprise mold compound such as epoxy with fillers or other suitable material. A redistribution layer comprising another organic dielectric material 118 may be on one or both sides of organic dielectric material 116. Organic dielectric material 116 and bridge die 114 may be considered to form a “core” of package substrate 102. The redistribution layer may further comprise a plurality of layers of conductive traces 120 and conductive vias 122. Conductive traces 120 on either side of organic dielectric material 116 may be conductively coupled by TDVs 124 (also referred to as TMVs). In some embodiments, an underfill 126 may be between IC die 108 and package substrate 102. Examples of materials comprising underfill 126 are described in the previous subsection. In some embodiments, a mold compound 128 may encapsulate, or at least surround, IC dies 108.

In various embodiments, the pitch between adjacent interconnects 110 may range from 10 micrometers to 200 micrometers. Some interconnects 110 may be larger than other interconnects 110; the larger ones of interconnects 110 may have a correspondingly larger pitch than the smaller ones of interconnects 110. For example, some interconnects conductively coupled to TDVs 124 may be larger than other interconnects 110 conductively coupled to bridge die 114. Interconnects 110 and 112 may comprise solder in various embodiments, and other embodiments may not include solder. In various embodiments, interconnects 110 further comprise bumps on surface 109 of IC die 108 and bond-pads on surface 104 of package substrate 102, with the solder coupled to the bumps and the bond-pads. In addition, lateral surfaces of the bumps may have a coating of a material, such as silicon nitride that prevents solder wicking, and insulative baffles (e.g., barriers) on surface 104 of package substrate 102 may be provisioned between the bond-pads to prevent solder bridging or solder migration across adjacent interconnects 110. Such details are not shown in the figure so as not to clutter the drawing and may be more effectively explained in reference to a portion 150 in FIG. 1B.

FIG. 1B is a simplified cross-sectional view of portion 150 of microelectronic assembly 100. Some interconnects 110A may be larger than other interconnects 110B and respective features may be correspondingly differently sized too. Bond-pads 152 in IC die 108 may include bumps 154 that protrude (e.g., extend) from surface 109 of IC die 108. The protrusion may range from approximately 5 micrometers in some embodiments to 50 micrometers in other embodiments. Bumps 154 may have a lateral surface 153 orthogonal to surface 109 and a medial surface 155 parallel to surface 109. Medial surface 155 of bumps 154 may be conductively coupled to bond-pads 156 on surface 104 of package substrate 102 by solder 158. Lateral surfaces 153 of bumps 154 may be covered partially or wholly with a coating 160 comprising a material that prevents solder wicking. An example of such a material includes silicon nitride in embodiments where solder 158 includes tin (or other lead-free solder). In another example, coating 160 comprises a surface finish generated by treating lateral surfaces 153 of bumps 154 with fluorinated plasma. Fluorine atoms upon combination with carbon can form various compounds that can modify surface wettability, decrease coefficient of friction, etc. suitable for coating 160.

In some embodiments, bond-pads 156 may have suitable surface finish for solder 158, including electroless nickel electroless palladium immersion gold (ENEPIG). In various embodiments, a baffle layer 162 may be disposed on surface 104 of package substrate 102. Baffle layer 162 may comprise an insulative organic material such as solder resist. Baffle layer 162 may comprise openings 164 over bond-pads 156. In the embodiment shown in the figure, a diameter 166 of any one bond-pad 156 is smaller than a diameter 168 of corresponding opening 164. In some other embodiments (described below in reference to FIG. 1D), diameter 166 may be greater than diameter 168. In yet other embodiments (not shown) some bond-pads 156 may have diameter 166 greater than diameter 168 of corresponding opening 164 and other bond-pads 156 may have diameter 166 smaller than diameter 168 of corresponding opening 164.

In embodiments where diameter 166 of bond-pad 156 is smaller than diameter 168 of opening 164, solder 158 may overflow over and contact lateral surface 157 of bond-pad 156. A surface 159 of solder 158 may be disposed in opening 164 between lateral surface 157 of bond-pad 156 and lateral surface 169 of openings 164. In some embodiments, the presence of coating 160 on lateral surface 153 of bump 154 may prevent solder 158 from riding up around bump 154; consequently, solder 158 may instead contact other available surfaces (e.g., surfaces 157, 169) within opening 164. Additionally, insulative baffle layer 162 may thick enough to prevent solder 158 overflowing out of any opening 164 and bridging with solder 158 in adjacent openings 164.

FIG. 1C shows a perspective view of a part of portion 150 of microelectronic assembly 100 cut along a surface of baffle layer 162. Openings 164 in baffle layer 162 is shown more clearly than in FIG. 1B, with underfill material 126 removed for better visibility.

FIG. 1D shows a cross-sectional view of portion 150 of another example microelectronic assembly 100 according to various embodiments. The embodiment of the figure is substantially similar to that of FIGS. 1B and 1C except that diameter 166 of bond-pads 156 is greater than diameter 168 of openings. In such embodiments, solder 158 may ride up surface 169 of openings 164, partially covering lateral surface 169 of openings 164. Coating 160 on bumps 154 may prevent wicking, and thus solder 158 may predominantly lie closer to other surfaces, for example, surface 169 or 104 of package substrate 102. A thickness 170 of baffle layer 162 may be between the sum of thicknesses of bump 152 over surface 109, solder 158 and bond-pad 156 and another sum of thicknesses of solder 158 and bond-pad 156. 16. Further, a volume of solder 158 in opening 164 may be such that it does not overflow out of opening 164 during assembly processes.

In various embodiments, any of the features discussed with reference to any of FIGS. 1A-1D herein may be combined with any other features to form a package with one or more IC dies as described herein. For example, in some microelectronic assemblies, some IC dies may be coupled by interconnects having solder and other IC dies may be coupled by non-solder bonds. Some such combinations are described above, but, in various embodiments, further combinations and modifications are possible. Various different embodiments described in different figures may be combined suitably based on particular needs within the broad scope of the embodiments.

### Example Methods

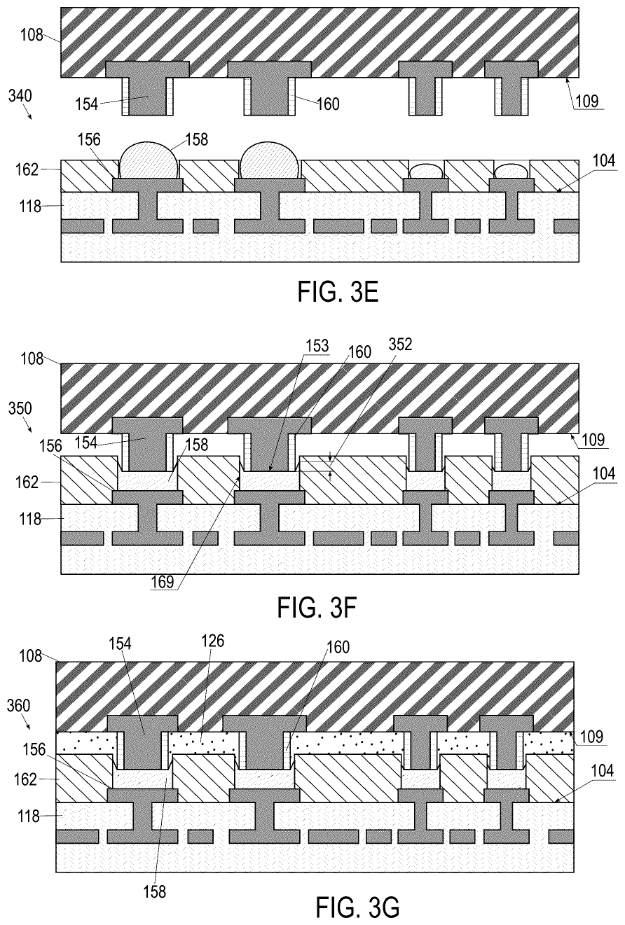

FIGS. 2A-2C are schematic cross-sectional views of various stages of manufacture of IC die 108. FIG. 2A shows a portion 200 of a panel, wafer or individual one of IC die 108. Bond-pads 152 and bumps 154 may be provided on surface 109 of IC die 108. Portion 200 shows a few bond-pads 152 of IC die 108. It is to be understood that other components of IC die 108 are not shown in the figures. Such is merely for ease of illustration and description. The processes shown and described in FIGS. 2A-2C apply to the entirety of the panel, wafer or individual one of IC die 108 and not only to the specific portion 200 shown in the figures.

FIG. 2B shows a portion 210 of the panel, wafer or individual one of IC die 108 subsequent to deposition of a passivation layer 212. Passivation layer 212 may be silicon nitride in some embodiments. In such embodiments, passivation layer 212 may be deposited by physical vapor deposition (PVD) or chemical vapor deposition (CVD). In some other embodiments, bumps 152 and surface 109 may be treated with fluorinated plasma, for example, by plasma-enhanced CVD, also called plasma polymerization, which deposits passivation layer 212 (or alters surface properties to create passivation layer 212).

FIG. 2C shows a portion 220 of the panel, wafer or individual one of IC die 108 subsequent to selectively etching passivation layer 212. Passivation layer 212 on surfaces parallel to surface 109 including medial surfaces 155 of bumps 154 and surface 109 may be etched away, leaving coating 160 on lateral surfaces 153. Subsequently, the panel or wafer may be diced to separate individual ones of IC die 108.

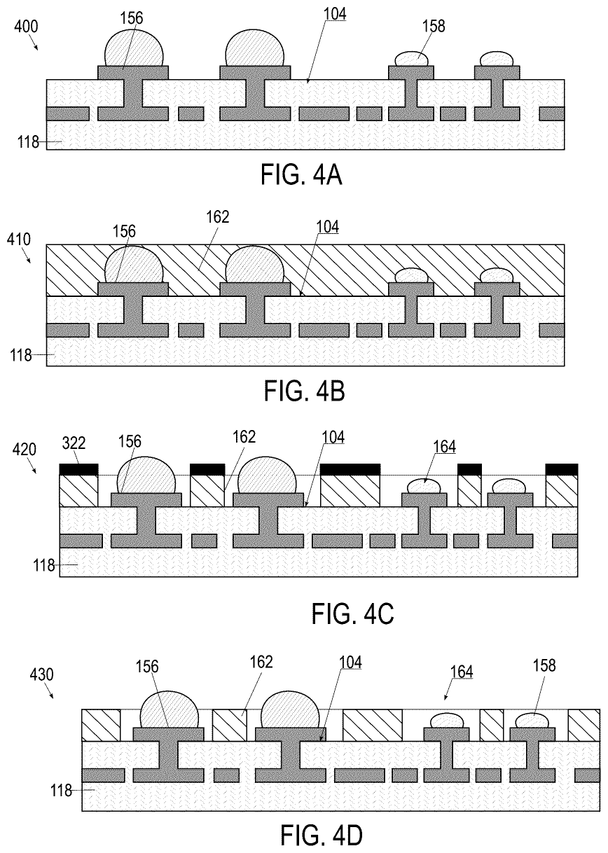

FIGS. 3A-3G are schematic cross-sectional views of various stages of manufacture of microelectronic assembly 100. FIG. 3A shows a portion 300 of a panel or individual one of package substrate 102. Portion 300 shows a few conductive traces 120 and bond-pads 156 on organic dielectric material 118. It is to be understood that other components of package substrate 102 are not shown in the figures. Such is merely for ease of illustration and description. The processes shown and described in FIGS. 3A-3G apply to the entirety of the panel, wafer or individual one of package substrate 102 and not only to the specific portion 300 shown in the figures. Some bond-pads 156A are larger than other bond-pads 156B and may be spaced apart according to correspondingly different pitches. Bond-pads 156 may protrude from surface 104 in various embodiments. In other embodiments, bond-pads 156 may be flush (e.g., coplanar) with surface 104.

FIG. 3B shows a portion 310 of microelectronic assembly 100 subsequent to further processing on portion 300. Baffle layer 162, for example, comprising solder resist, may be deposited on surface 104 of package substrate 102, for example, dispensed in liquid form and subsequently cured. In some embodiments, baffle layer 162 may comprise buildup film, which may be pasted over surface 104.

FIG. 3C shows a portion 320 of microelectronic assembly 100 subsequent to further processing on portion 310. A mask 322 may be deposited on baffle layer 162, mask 322 comprising openings corresponding to openings 164 and bond-pads 156. Openings 164 in baffle layer 162 may be created according to the pattern of mask 322. In some embodiments, openings 164 may be created by wet or dry etching. In other embodiments, openings 164 may be created by laser drilling. Any suitable process known in the art may be used to create openings 164.

FIG. 3D shows a portion 330 of microelectronic assembly 100 subsequent to further processing on portion 320. Solder 158 may be deposited on bond-pads 156 in openings 164. In the embodiment shown in the figure, openings 164 are smaller than bond-pads 156; in other embodiments, openings 164 may be larger than bond-pads 156. In some embodiments, prior to depositing solder 158, an appropriate surface finish (e.g., ENEPIG) may be coated on bond-pads 156.

FIG. 3E shows a portion 340 of microelectronic assembly 100 subsequent to further processing on portion 330. IC die 108 may be aligned over package substrate 102 such that bumps 154 are aligned to bond-pads 156 appropriately.

FIG. 3F shows a portion 350 of microelectronic assembly 100 subsequent to further processing on portion 340. TCB may be performed to bond solder 158 to bumps 154. During the TCB process, the assembly may be subject to high temperatures and pressure, with IC die 108 being pushed against and downward on package substrate 102. Consequently, solder 158 may flow outward from underneath bumps 154 and occupy other available space in respective openings 164. Because bumps 154 are covered with coating 160 that prevents solder wicking, and openings 164 are smaller than bond-pads 156, solder 158 may creep up lateral sides 169 of openings 164, away from bumps 154, with a convex surface having an outer edge along surface 169 that is higher by an amount 352 than medial surface 153 of bumps 154.

FIG. 3G shows a portion 350 of microelectronic assembly 100 subsequent to further processing on portion 340. Underfill 126 may be dispensed between IC die 108 and package substrate 102. Underfill 126 may fill any available space in openings 164 and around bumps 154 between IC die 108 and package substrate 102.

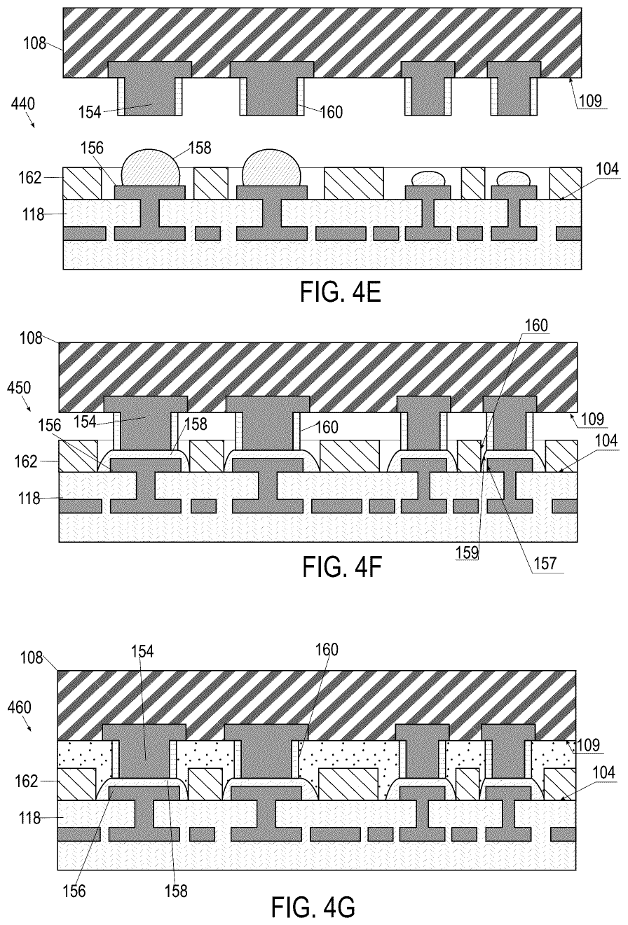

FIGS. 4A-4G are schematic cross-sectional views of various stages of manufacture of microelectronic assembly 100. FIG. 4A shows a portion 400 of a panel or individual one of package substrate 102. Portion 400 shows a few conductive traces 120 and bond-pads 156 on organic dielectric material 118. It is to be understood that other components of package substrate 102 are not shown in the figures. Such is merely for ease of illustration and description. The processes shown and described in FIGS. 4A-4G apply to the entirety of the panel, wafer or individual one of package substrate 102 and not only to the specific portion 400 shown in the figures. In various embodiments, solder 158 may be deposited on bond-pads 156 as shown. In some embodiments, prior to depositing solder 158, an appropriate surface finish (e.g., ENEPIG) may be coated on bond-pads 156.

FIG. 4B shows a portion 410 of microelectronic assembly 100 subsequent to further processing on portion 400. Baffle layer 162, for example, comprising solder resist, may be deposited on surface 104 of package substrate 102, for example, dispensed in liquid form and subsequently cured. In some embodiments, baffle layer 162 may comprise buildup film, which may be pasted over surface 104. Baffle layer 164 may cover solder 158 on bond-pads 156.

FIG. 4C shows a portion 420 of microelectronic assembly 100 subsequent to further processing on portion 410. Mask 322 may be deposited on baffle layer 162, mask 322 comprising openings corresponding to openings 164 and bond-pads 156. Openings 164 in baffle layer 162 may be created according to the pattern of mask 322. In the embodiment shown in the figure, openings 164 are larger than bond-pads 156; in other embodiments, openings 164 may be smaller than bond-pads 156. Baffle layer 162 may be dry-etched to create openings 164. Such dry-etch processes are compatible with solder 158 (i.e., the etching process may remove only material from baffle layer 162 and may leave solder 158 intact).

FIG. 4D shows a portion 430 of microelectronic assembly 100 subsequent to further processing on portion 420. Mask 322 may be removed, for example, by etching.

FIG. 4E shows a portion 440 of microelectronic assembly 100 subsequent to further processing on portion 430. IC die 108 may be aligned over package substrate 102 such that bumps 154 are aligned to bond-pads 156 appropriately.

FIG. 4F shows a portion 450 of microelectronic assembly 100 subsequent to further processing on portion 440. TCB may be performed to bond solder 158 to bumps 154. During the TCB process, the assembly may be subject to high temperatures and pressure, with IC die 108 being pushed against and downward on package substrate 102. Consequently, solder 158 may flow outward from underneath bumps 154 and occupy other available space in respective openings 164. Because bumps 154 are covered with coating 160 that prevents solder wicking, and openings 164 are larger than bond-pads 156, solder 158 may flow down lateral sides 157 of bond-pads 156, away from bumps 154, with a convex surface having an outer edge between surfaces 169 and 157.

FIG. 4G shows a portion 450 of microelectronic assembly 100 subsequent to further processing on portion 440. Underfill 126 may be dispensed between IC die 108 and package substrate 102. Underfill 126 may fill any available space in openings 164 and around bumps 154 between IC die 108 and package substrate 102.

Although FIGS. 2-4 illustrate various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 2-4 may be modified in accordance with the present disclosure to fabricate others of microelectronic assembly 100 disclosed herein. Although various operations are illustrated in FIGS. 2-4 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 2-4 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in the figure may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

### Example Devices and Components

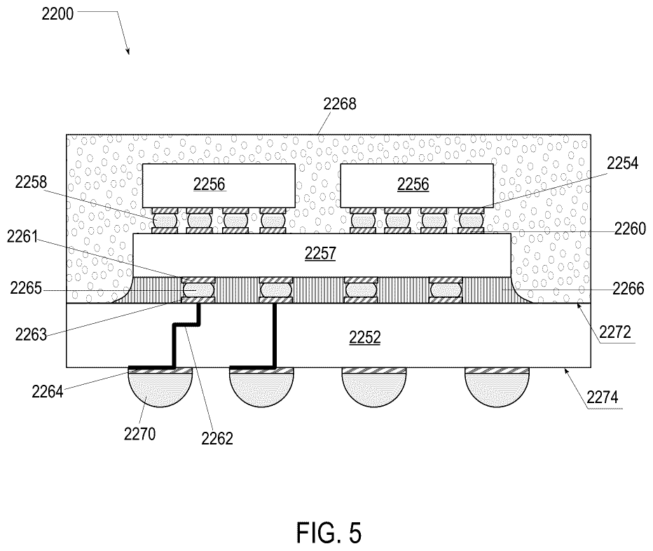

The packages disclosed herein, e.g., any of the embodiments shown in FIGS. 1-4 or any further embodiments described herein, may be included in any suitable electronic component. FIGS. 5-7 illustrate various examples of packages, assemblies, and devices that may be used with or include any of the IC packages as disclosed herein.

FIG. 5 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

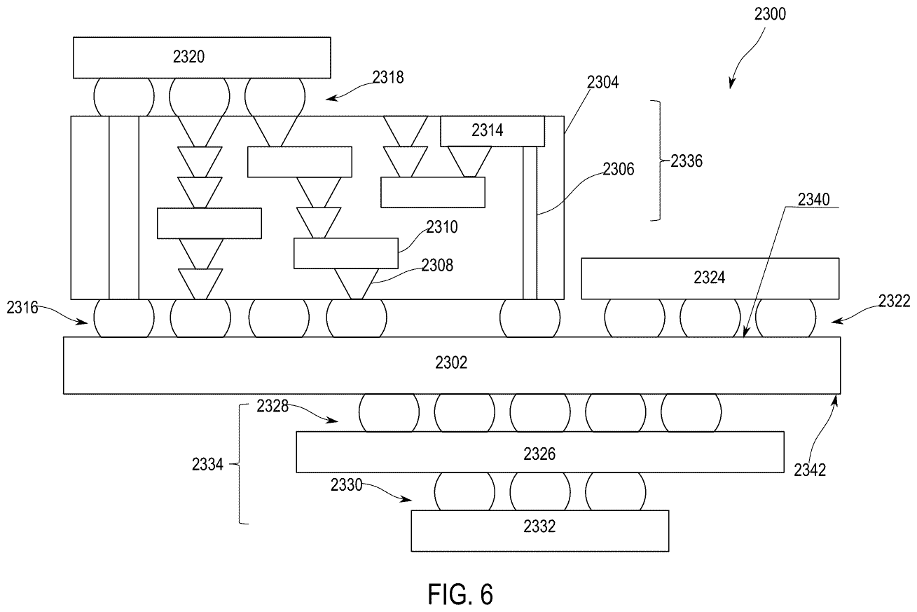

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 6.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 6 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 5.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 5. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328.

Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

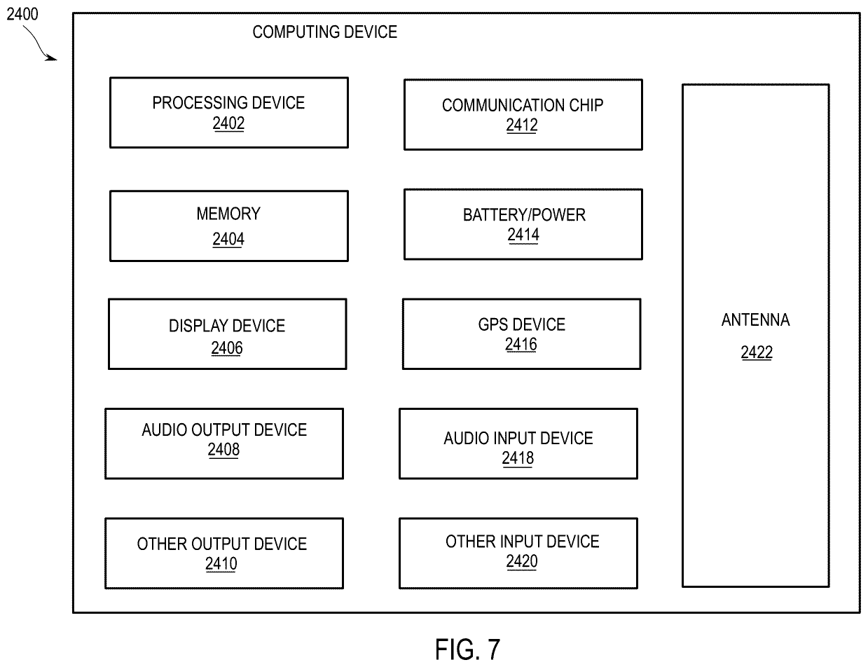

FIG. 7 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 5). In yet another example, any one or more of the components of computing device 2400 may include an IC device assembly 2300 (e.g., as shown in FIG. 6).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIGS. 1A, 1B), comprising: a package substrate (e.g., 102); and an IC die (e.g., 108) coupled to a surface (e.g., 104) of the package substrate by first interconnects (e.g., 152A) and second interconnects (e.g., 152B), the first interconnects and the second interconnects comprising solder, in which: the first interconnects are larger than the second interconnects, the first interconnects and the second interconnects further comprise bumps (e.g., 154) on the IC die and bond-pads (e.g., 156) on the surface of the package substrate, with the solder (e.g., 158) coupled to the bumps and the bond-pads, lateral surfaces (e.g., 153) of the bumps have a coating (e.g., 160) of a material that prevents solder wicking, and insulative baffles (e.g., 162) on the surface of the package substrate are between the bond-pads.

Example 2 provides the microelectronic assembly of example 1, in which the insulative baffles is configured to prevent solder bridging between adjacent bond-pads.

Example 3 provides the microelectronic assembly of any of examples 1-2, in which the solder is one of lead solder or lead-free solder.

Example 4 provides the microelectronic assembly of any of examples 1-3, in which the coating on the bumps is a compound comprising silicon and nitrogen.

Example 5 provides the microelectronic assembly of any of examples 1-3, in which the coating comprises a surface finish generated by treating the lateral surfaces of the bump with fluorinated plasma.

Example 6 provides the microelectronic assembly of any of examples 1-5, in which the bumps on the IC die protrude from a surface (e.g., 109) of the IC die.

Example 7 provides the microelectronic assembly of example 6, in which the bumps protrude approximately 5 micrometers to 50 micrometers from the surface of the IC die.

Example 8 provides the microelectronic assembly of any of examples 1-7, further comprising an underfill (e.g., 126) between the IC die and the package substrate around the first interconnects and the second interconnects.

Example 9 provides the microelectronic assembly of any of examples 1-9, further comprising a mold compound (e.g., 128) around the IC die.

Example 10 provides the microelectronic assembly of any of examples 1-10, in which the insulative baffles comprise solder resist.

Example 11 provides the microelectronic assembly of any of examples 1-11, in which the solder covers lateral surfaces (e.g., 157) of the bond-pads.

Example 12 provides the microelectronic assembly of example 11, in which a surface (e.g., 159) of the solder is between the lateral surfaces of the bond-pads and the insulative baffles.

Example 13 provides the microelectronic assembly of any of examples 1-12, in which the bond-pads are in openings (e.g., 164) in the insulative baffles.

Example 14 provides the microelectronic assembly of any of examples 1-13, in which: the first interconnects are spaced apart according to a first pitch, the second interconnects are spaced apart according to a second pitch, and the first pitch is larger than the second pitch.

Example 15 provides the microelectronic assembly of example 14, in which the first pitch or the second pitch is between 10 micrometers and 200 micrometers.

Example 16 provides the microelectronic assembly of any of examples 1-15, in which: the first interconnects conductively couple the IC die to a TDV (e.g., 124) in the package substrate, and the second interconnects conductively couple the IC die to a bridge die (e.g., 114) in the package substrate.

Example 17 provides a package substrate (e.g., 102 FIGS. 1B, 1C), comprising: a core comprising a first organic dielectric material (e.g., 116) and TDVs (e.g., 124) in the first organic dielectric material; a first layer comprising a second organic dielectric material (e.g., 118) and a conductive bond-pad (e.g., 156) of a first diameter (e.g., 166); and a second layer on a surface of the package substrate, the second layer comprising an opening (e.g., 164) of a second diameter (e.g., 168), in which: the first layer is between the core and the second layer, the bond-pad is at an interface between the first layer and the second layer, the bond-pad is in the opening in the second layer, and the first diameter of the bond-pad is smaller than the second diameter of the opening.

Example 18 provides the package substrate of example 17, further comprising a plurality of bond-pads and corresponding openings, in which some bond-pads are larger than other bond-pads.

Example 19 provides the package substrate of example 18, in which: the package substrate is coupled to an IC die by solder on individual bond-pads in the plurality of bond-pads, the solder conductively couples the individual bond-pads to corresponding bumps on the IC die, and the solder covers lateral surfaces (e.g., 157) of the individual bond-pads in a space between the individual bond-pads and the openings.

Example 20 provides the package substrate of example 19, in which a surface (e.g., 159) of the solder is between lateral surfaces of the individual bond-pads and the corresponding openings.

Example 21 provides the package substrate of any of examples 19-20, in which: the second layer has a first thickness, the individual bond-pads have a second thickness, the solder has a third thickness, the bumps on the IC die have a fourth thickness, and the first thickness of the second layer is between a sum of the second thickness of the bond-pads and the third thickness of the solder, and another sum of the second thickness of the bond-pads, the third thickness of the solder and the fourth thickness of the bumps.

Example 22 provides the package substrate of any of examples 17-21, in which: the first organic dielectric material comprises mold compound, and the second organic dielectric material comprises polyimide or buildup film.

Example 23 provides the package substrate of any of examples 17-22, further comprising a bridge die (e.g., 114) in the core, in which the TDVs are around the bridge die.

Example 24 provides the package substrate of any of examples 17-23, in which the bond-pads comprise ENEPIG surface finish.

Example 25 provides the package substrate of any of examples 17-24, in which the first layer comprises conductive traces (e.g., 120) and conductive vias (e.g., 122).

Example 26 provides the package substrate of any of examples 17-25, further comprising a third layer on a side of the core opposite to the first layer.

Example 27 provides a package substrate (e.g., 102 FIG. 1D), comprising: a core comprising a first organic dielectric material (e.g., 116) and TDVs (e.g., 124) in the first organic dielectric material; a first layer comprising a second organic dielectric material (e.g., 118) and a conductive bond-pad (e.g., 156) of a first diameter (e.g., 166); and a second layer on a surface of the package substrate, the second layer comprising an opening (e.g., 164) of a second diameter (e.g., 168), in which: the first layer is between the core and the second layer, the bond-pad is at an interface between the first layer and the second layer, the bond-pad is in the opening in the second layer, and the first diameter of the bond-pad is larger than the second diameter of the opening.

Example 28 provides the package substrate of example 27, further comprising a plurality of bond-pads and corresponding openings, in which some bond-pads are larger than other bond-pads.

Example 29 provides the package substrate of example 28, in which: the package substrate is coupled to an IC die by solder on individual bond-pads in the plurality of bond-pads, the solder conductively couples the individual bond-pads to corresponding bumps on the IC die, and the solder partially covers lateral surfaces of the corresponding openings without overflowing out of the corresponding openings in the second layer.

Example 30 provides the package substrate of example 29, in which the lateral surfaces of the corresponding bumps are coated with a material that inhibit solder wicking.

Example 31 provides the package substrate of any of examples 29-30, in which: the second layer has a first thickness, the individual bond-pads have a second thickness, the solder has a third thickness, the bumps on the IC die have a fourth thickness, and the first thickness of the second layer is between a sum of the second thickness of the bond-pads and the third thickness of the solder, and another sum of the second thickness of the bond-pads, the third thickness of the solder and the fourth thickness of the bumps.

Example 32 provides the package substrate of any of examples 27-31, in which: the first organic dielectric material comprises mold compound, and the second organic dielectric material comprises polyimide or buildup film.

Example 33 provides the package substrate of any of examples 27-32, further comprising a bridge die (e.g., 114) in the core, in which the TDVs are around the bridge die.

Example 34 provides the package substrate of any of examples 27-33, in which the bond-pads comprise ENEPIG surface finish.

Example 35 provides the package substrate of any of examples 27-34, in which the first layer comprises conductive traces (e.g., 120) and conductive vias (e.g., 122).

Example 36 provides the package substrate of any of examples 27-35, further comprising a third layer on a side of the core opposite to the first layer.

Example 37 provides a microelectronic assembly (e.g., 100, FIGS. 1A, 1B), comprising: a first substrate (e.g., 102); and a second substrate (e.g., 108) coupled to a surface (e.g., 104) of the first substrate by first interconnects (e.g., 152A) and second interconnects (e.g., 152B), the first interconnects and the second interconnects comprising solder, in which: the first interconnects are larger than the second interconnects, the first interconnects and the second interconnects further comprise bumps (e.g., 154) on the second substrate and bond-pads (e.g., 156) on the surface of the first substrate, with the solder (e.g., 158) coupled to the bumps and the bond-pads, lateral surfaces (e.g., 153) of the bumps have a coating (e.g., 160) of a material that prevents solder wicking, and insulative baffles (e.g., 162) on the surface of the first substrate are between the bond-pads.

Example 38 provides the microelectronic assembly of example 37, in which the insulative baffles is configured to prevent solder bridging between adjacent bond-pads.

Example 39 provides the microelectronic assembly of any of examples 37-38, in which the coating on the bumps is a compound comprising silicon and nitrogen.

Example 40 provides the microelectronic assembly of any of examples 37-39, in which the coating comprises a surface finish generated by treating the lateral surfaces of the bump with fluorinated plasma.

Example 41 provides the microelectronic assembly of any of examples 37-40, in which the bumps on the second substrate protrude from a surface (e.g., 109) of the second substrate.

Example 42 provides the microelectronic assembly of any of examples 37-41, further comprising an underfill (e.g., 126) between the first substrate and the second substrate around the first interconnects and the second interconnects.

Example 43 provides the microelectronic assembly of any of examples 37-42, in which the insulative baffles comprise solder resist.

Example 44 provides the microelectronic assembly of any of examples 37-43, in which the solder covers lateral surfaces (e.g., 157) of the bond-pads on the first substrate.

Example 45 provides the microelectronic assembly of any of examples 37-44, in which an edge of the solder in contact with the baffles is between a surface of the second substrate and medial surfaces of the bumps.

Example 46 provides a method, comprising: providing an IC die with bumps (e.g., 154) extending from a surface (e.g., 109) of the IC die such that each bump has a lateral surface (e.g., 153) orthogonal to the surface of the IC die and a medial surface (e.g., 155) parallel to the surface of the IC die; depositing a passivation layer (e.g., 212) on the surface of the IC die and the bumps such that the passivation layer covers the surface of the IC die, the lateral surfaces of the bumps and the medial surfaces of the bumps; and etching away the passivation layer on the medial surfaces of the bumps.

Example 47 provides the method of example 46, further comprising etching away the passivation layer on the surface of the IC die.

Example 48 provides the method of any of examples 46-47, in which the passivation layer is a compound comprising silicon and nitrogen.

Example 49 provides the method of any of examples 46-48, in which the bumps are conductively coupled to bond-pads on the IC die.

Example 50 provides the method of any of examples 46-49, in which some bumps are larger than other bumps.

Example 51 provides a method, comprising: providing a package substrate (e.g., FIG. 3A) including: a core with TDVs (e.g., 124) in a first organic dielectric material (e.g., 116); and a first layer comprising a second organic dielectric material (e.g., 118) and conductive bond-pads of different sizes; depositing a second layer over the first layer (e.g., FIG. 3B); patterning the second layer to create openings over the bond-pads (e.g., FIG. 3C); depositing solder on the bond-pads (e.g., FIG. 3D); providing an IC die having bumps extending from a surface of the IC die, lateral surfaces of each bump coated with a material configured to prevent solder wicking (e.g., FIG. 3E); attaching the IC die to the package substrate (e.g., FIG. 3F); and depositing underfill between the IC die and the package substrate.

Example 52 provides the method of example 51, in which the second layer comprises solder resist.

Example 53 provides the method of any of examples 51-52, in which patterning the second layer comprises photolithography and dry etching.

Example 54 provides the method of any of examples 51-52, in which patterning the second layer comprises laser drilling.

Example 55 provides the method of any of examples 53-54, in which the openings are larger than corresponding bond-pads.

Example 56 provides the method of any of examples 53-54, in which the openings are smaller than corresponding bond-pads.

Example 57 provides the method of any of examples 51-56, in which the material coating lateral surfaces of each bump is a compound comprising silicon and nitrogen.

Example 58 provides the method of any of examples 51-57, in which some bond-pads are larger than other bond-pads.

Example 59 provides the method of any of examples 51-58, in which attaching the IC die comprises thermo-compression bonding.

Example 60 provides the method of any of examples 51-59, in which the underfill fills any gaps between the solder and surfaces of the openings in the second layer.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a package substrate; and
an integrated circuit (IC) die coupled to a surface of the package substrate by first interconnects and second interconnects, the first interconnects and the second interconnects comprising solder,
wherein:
the first interconnects are larger than the second interconnects,
the first interconnects and the second interconnects further comprise bumps on the IC die and bond-pads on the surface of the package substrate, with the solder coupled to the bumps and the bond-pads,
lateral surfaces of the bumps have a coating of a material that prevents solder wicking, and
insulative baffles on the surface of the package substrate are between the bond-pads.

2. The microelectronic assembly of claim 1, wherein the solder is one of lead solder or lead-free solder.

3. The microelectronic assembly of claim 2, wherein the coating on the bumps is a compound comprising silicon and nitrogen.

4. The microelectronic assembly of claim 1, wherein the bumps on the IC die protrude from a surface of the IC die.

5. The microelectronic assembly of claim 1, further comprising an underfill between the IC die and the package substrate around the first interconnects and the second interconnects.

6. The microelectronic assembly of claim 1, wherein the insulative baffles comprise solder resist.

7. The microelectronic assembly of claim 1, wherein the bond-pads are in openings in the insulative baffles.

8. The microelectronic assembly of claim 1, wherein:
the first interconnects conductively couple the IC die to a through-dielectric via (TDV) in the package substrate, and
the second interconnects conductively couple the IC die to a bridge die in the package substrate.

9. A package substrate, comprising:
a core comprising a first organic dielectric material and TDVs in the first organic dielectric material;
a first layer comprising a second organic dielectric material and a conductive bond-pad of a first diameter; and
a second layer on a surface of the package substrate, the second layer comprising an opening of a second diameter,
wherein:
the first layer is between the core and the second layer,
the bond-pad is at an interface between the first layer and the second layer,
the bond-pad is in the opening in the second layer, and
the first diameter of the bond-pad is smaller than the second diameter of the opening.

10. The package substrate of claim 9, further comprising a plurality of bond-pads and corresponding openings, wherein some bond-pads are larger than other bond-pads.

11. The package substrate of claim 10, wherein:
the package substrate is coupled to an IC die by solder on individual bond-pads in the plurality of bond-pads,
the solder conductively couples the individual bond-pads to corresponding bumps on the IC die, and
the solder covers lateral surfaces of the individual bond-pads in a space between the individual bond-pads and the openings.

12. The package substrate of claim 11, wherein a surface of the solder is between lateral surfaces of the individual bond-pads and the corresponding openings.

13. The package substrate of claim 9, wherein:
the first organic dielectric material comprises mold compound, and
the second organic dielectric material comprises polyimide or buildup film.

14. The package substrate of claim 9, further comprising a bridge die in the core, wherein the TDVs are around the bridge die.

15. A package substrate, comprising:
a core comprising a first organic dielectric material and TDVs in the first organic dielectric material;
a first layer comprising a second organic dielectric material and a conductive bond-pad of a first diameter; and
a second layer on a surface of the package substrate, the second layer comprising an opening of a second diameter,
wherein:
the first layer is between the core and the second layer,
the bond-pad is at an interface between the first layer and the second layer,
the bond-pad is in the opening in the second layer, and
the first diameter of the bond-pad is larger than the second diameter of the opening.

16. The package substrate of claim 15, further comprising a plurality of bond-pads and corresponding openings, wherein some bond-pads are larger than other bond-pads.

17. The package substrate of claim 16, wherein:
the package substrate is coupled to an IC die by solder on individual bond-pads in the plurality of bond-pads,
the solder conductively couples the individual bond-pads to corresponding bumps on the IC die, and
the solder partially covers lateral surfaces of the corresponding openings without overflowing out of the corresponding openings in the second layer.

18. The package substrate of claim 17, wherein the lateral surfaces of the corresponding bumps are coated with a material that inhibit solder wicking.

19. The package substrate of claim 15, wherein:
the first organic dielectric material comprises mold compound, and
the second organic dielectric material comprises polyimide or buildup film.

20. The package substrate of claim 15, further comprising a bridge die in the core, wherein the TDVs are around the bridge die.
